(19) United States
(12) Patent Application Publication
(10) Pub. No.: US 2007/0077738 A1
(43) Pub. Date: Apr. 5, 2007

(54) Fabrication of small scale matched bi-polar TVS devices having reduced parasitic losses

(76) Inventors: Aram Tanielian, Rancho Palos Verdes, CA (US); Garo Tanielian, Rolling Hills, CA (US)

Correspondence Address: Gene Scott;Patent Law & Venture Group, Suite 150, 3140 Red Hill Ave., Costa Mesa, CA, 92626-3440, US

(21) Appl. No.: 11/243,161

(22) Filed: Oct. 3, 2005

(51) Int. Cl. H01L 21/265; H01L 21/336

(52) U.S. Cl. 438/523; 438/268

(57) ABSTRACT

A method of fabricating plural bipolar transient voltage suppressors includes preparing a doped base material having a planar surface and then depositing onto the planar surface an doped epitaxial layer of opposite type thereby forming a semiconductor interface. The epitaxial layer is preferentially etched leaving mesas having side walls to the base material. An oxide layer is then deposited all over the upper surface and windows are etched in the oxide layer on the mesas. A high concentration of an appropriate dopant is diffused into the windows to establish ohmic contact surfaces for metallization of conductors. The base material is then bonded onto a substrate and cuts are made through to the base material so as to separate the mesas into adjacent pairs to provide plural bi-polar devices on the substrate.

### BACKGROUND

1. Field of the Present Disclosure

This disclosure relates generally to semiconductor devices and more particularly to a simplified method for fabricating bi-directional transient-voltage suppression devices.

2. Description of Related Art

Transient voltage suppressors (TVS) are typically manufactured using glass passivated mesa diodes. Bi-directional applications require two or more mounted and bonded diodes connected in a common cathode configuration. For monolithic multi-line devices a pair is required for each line. It is desirable to reduce the size of the packaged devices as well as the number of mounting and bonding steps required. It is also desirable to provide a method that produces higher yield at lower cost and with improved electrical characteristics by, for instance, having many, more evenly matched diodes.

Matteson et al., U.S. Pat. No. 6,867,436, is hereby incorporated by reference into the present disclosure and discloses a bi-directional transient voltage suppression (“TVS”) device including a semiconductor die that has a first avalanche diode in series with a first rectifier diode connected cathode to cathode, electrically coupled in an anti-parallel configuration with a second avalanche diode in series with a second rectifier diode also connected cathode to cathode. All the diodes of the TVS device are on a single semiconductor substrate. The die has a low resistivity buried diffused layer having a first conductivity type disposed between a semiconductor substrate having the opposite conductivity type and a high resistivity epitaxial layer having the first conductivity type. The buried diffused layer shunts most of a transient current away from a portion of the epitaxial layer between the first avalanche diode and the first rectifier diode, thereby reducing the clamping voltage relative to the breakdown voltage. The TVS device is packaged as a flip chip that has four solder bump pads. Park, U.S. Pat. No. 6,813,172, discloses a power supply circuit for a video display device including a power transformer for inducing a voltage with respect to an input voltage by using an interaction occurring between a primary coil and a secondary coil; a switching circuit unit for controlling the voltage to be induced at the secondary coil of the power transformer by switching on/off a current flowing along the primary coil of the power transformer; first and second TVS diodes serially connected to each other; first and second resistors parallel connected to the respective first and second TVS diodes; a capacitor parallel connected to both ends of the first and second TVS diodes connected to each other and being charged with the transient voltage in the reverse direction that is supplied through the primary coil of the power transformer; and a diode for forming a passage of current in one direction when the capacitor is charged. Napiorkowski, U.S. Pat. No. 6,680,839, discloses an apparatus and method for reducing and balancing the off-state capacitance of an over-voltage protection circuit utilizing one or more diode networks electrically connected in series with an over-voltage protection device. The over-voltage protection device is selected from the group consisting of a gas tube, an MOV, a transient voltage suppressor (TVS) diode and a TVS thyristor. Preferably, the over-voltage protection device is a solid-state over-voltage protector (SSOVP) having at least one thyristor. The diode network includes a plurality of diodes electrically connected in parallel and arranged with opposing polarities so that the circuit is bi-directional. Preferably, the diode network includes a first set of two or more stacked diodes electrically connected in parallel with a second set of two or more stacked diodes and arranged with opposing polarities, and the capacitance of the diode network is less than the capacitance of the thyristor. Einthoven et al., U.S. Pat. No. 6,858,510, is hereby incorporated into the present disclosure by reference and discloses a method of making a bi-directional transient voltage suppression device, which comprises: (a) providing a p-type semiconductor substrate; (b) epitaxially depositing a lower semiconductor layer of p-type conductivity; (c) epitaxially depositing a middle semiconductor layer of n-type conductivity over the lower layer; (d) epitaxially depositing an upper semiconductor layer of p-type conductivity over the middle layer; (e) heating the substrate, the lower epitaxial layer, the middle epitaxial layer and the upper epitaxial layer; (f) etching a mesa trench that extends through the upper layer, through the middle layer and through at least a portion of the lower layer, such that the mesa trench defines an active area for the device; and (g) thermally growing an oxide layer on at least those portions of the walls of the mesa trench that correspond to the upper and lower junctions of the device. Frister et al., U.S. Pat. No. 4,347,543, discloses a diode array, in a rectifier circuit structure, particularly for automotive use, in the form of a column and including a Zener diode in the column which serves to protect the rectifier diodes of the arrangement and to protect an electrical load system coupled to the output of the diode array. Alderman, U.S. Pat. No. 4,445,003, discloses a simplified combination of privacy circuits and holding circuits for use on a telephone subscriber loop. The circuit arrangement includes a diode array within a conventional full wave rectifier bridge having a pair of interchangeable terminals and a third differentiated terminal for connection in the loop. The interchangeable terminals are connected in series with either the tip or ring conductor with the remaining terminal connected to the other conductor. The combination of diode array and bridge assures that, irrespective of the connection arrangement, the hold circuit always shunts the series combination of telephone and privacy circuit. A novel self limiting amplifier stage including a plurality of diodes shunting the collector to emitter output of a transistor is disclosed for injecting a music-on-hold signal when the hold circuit is active. Additionally, a capacitance in the gate to cathode circuit of a thyristor in the hold circuit can be charged to a voltage exceeding the on state gate to cathode voltage. A path for discharging the capacitance is provided when the thyristor momentarily shuts off during a momentary loop current interruption to retrigger the SCR solely through the gate to cathode circuit without the use of switching circuits connected to the anode side of the SCR. Einthoven et al., U.S. Pat. No. 6,489,660, discloses a bi-directional transient voltage suppression device with symmetric current-voltage characteristics having a lower semiconductor layer of first conductivity type, an upper semiconductor layer of first conductivity type, and a middle semiconductor layer adjacent to and disposed between the lower and upper layers having a second opposite conductivity type, such that upper and lower p−n junctions are formed. The middle layer has a net doping concentration that is highest at a midpoint between the junctions. Furthermore, the doping profile along a line normal to the lower, middle and upper layers is such that, within the middle layer the doping profile on one side of a center plane of the middle layer mirrors the doping profile on an opposite side. In addition, an integral of the net doping concentration of the middle layer taken over the distance between the junctions is such that breakdown, when it occurs, is punch through breakdown, rather than avalanche breakdown. Clark et al., U.S. Pat. No. 5,539,604, discloses a protection apparatus for sensitive electronic circuitry susceptible to damage from transient voltage pulses. The apparatus includes sensitive circuitry and a transient voltage suppressor device mounted on a common circuit board or substrate. The transient voltage suppressor device comprises a semiconductor chip having a plurality of electrodes on a single major surface of the chip, the plurality of electrodes comprises over the half the area of the major surface of the chip and are mounted to surface conductors of the circuit board. The chip may contain a plurality of transient voltage suppression devices.

Our prior art search described above teaches the fabrication and use of low voltage punch-through bi-directional TVS devices having surface breakdown protection and in particular the fabrication of such devices having an avalanche diode as one element. However, the prior art does not disclose a simplified method of fabricating a multi-line bi-directional TVS device such as is disclosed herein. The present disclosure distinguishes over the prior art providing heretofore unknown advantages as described in the following summary.

### SUMMARY

This disclosure teaches certain benefits in construction and use which give rise to the objectives described below.

Described below is a method for fabricating a multi-line bidirectional TVS diode array. The device consists of pairs of silicon n/p+/n or p−/n+/p oxide passivated mesa diodes mounted on an inert substrate. A silicon wafer upon which the mesa diodes are fabricated is bonded to the inert substrate and diode pairs with a common cathode are then isolated by cutting through the silicon cathode area to the substrate. The substrate is then cut through to separate out a desired number of diode pairs. This yields a multi-line bidirectional TVS chip which can be flip chip mounted or wire bonded. Since the diode pairs are adjacent devices on the same chip, the result is a small scale matched bi-polar device with reduced parasitic losses.

A primary objective inherent in the above described apparatus and method of use is to provide advantages not taught by the prior art.

Another objective is to provide a method of fabricating bipolar voltage suppressors having low parasitic losses.

A further objective is to provide such an apparatus able to be made using an extremely simple fabrication technique which results in unusually high yield.

A still further objective is to provide such an apparatus able to be made at low cost.

Other features and advantages of the described apparatus and method of use will become apparent from the following more detailed description, taken in conjunction with the accompanying drawings, which illustrate, by way of example, the principles of the presently described apparatus and method of its use.

### BRIEF DESCRIPTION OF THE DRAWINGS

The accompanying drawings illustrate at least one of the best mode embodiments of the present apparatus and method of it use. In such drawings the present method is illustrated according to the sequence of steps necessary to form the present TVS devices, as follows:

FIG. 1 is a vertical sectional view of a base material such as a doped silicon wafer with an epitaxial layer deposited on top and an oxide layer on top of the epitaxial layer;

FIG. 2 shows the result of etching the oxide layer into separate rectangular domains;

FIG. 3 shows the result of further etching the epitaxial layer down to the silicon wafer using the oxide as a mask to form mesas and then passivating the exposed surfaces;

FIG. 4 shows the result of opening windows through the oxide on top of the mesas, forming ohmic contacts in the windows and then depositing a conductive layer within the windows;

FIG. 5 shows the result of bonding the silicon wafer to an inert substrate and then separating the devices by cutting into the base to open an air gap establishing isolation; and

FIG. 6 is a plan view of a 24 line bidirectional TVS chip with package made in accordance with the present inventive method and depicting an arrangement of electrical interconnection showing lines and grounds.

### DETAILED DESCRIPTION

The above described drawing figures illustrate the described apparatus and its method of fabrication in at least one of its preferred, best mode embodiment, which is further defined in detail in the following description. Those having ordinary skill in the art may be able to make alterations and modifications to what is described herein without departing from its spirit and scope. Therefore, it should be understood that what is illustrated herein is set forth only for the purposes of example and that it should not be taken as a limitation to the scope of the present apparatus and method of construction.

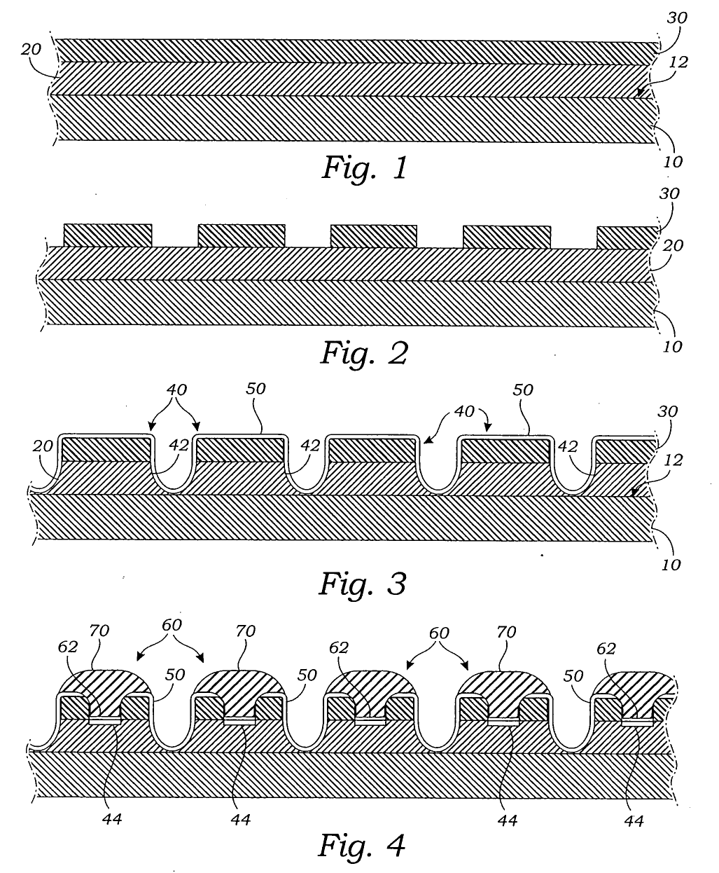

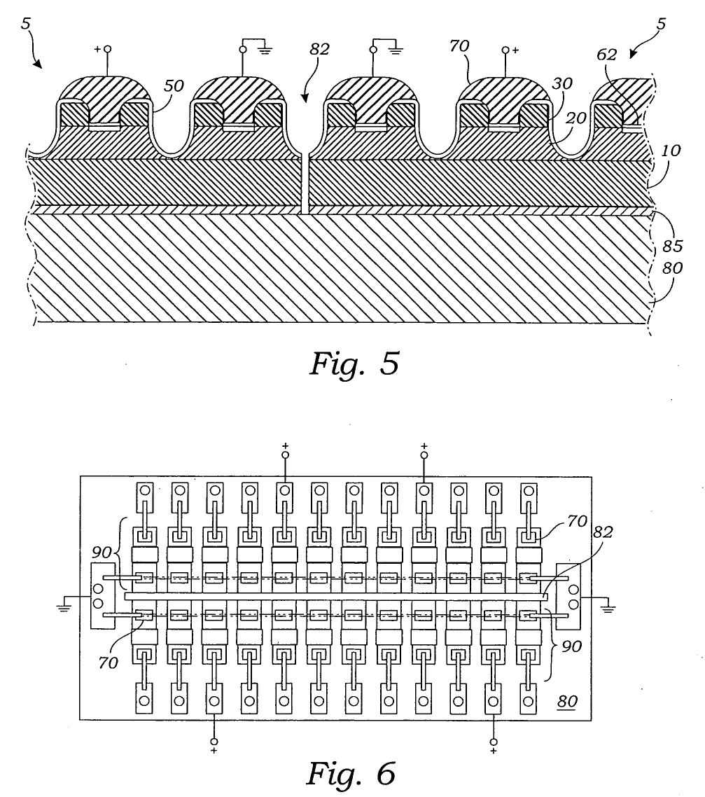

The present description defines a method of fabricating plural bipolar transient voltage suppressors (TVS) devices 5. The method includes preparing a p++ doped base material 10 having a planar surface 12 and then depositing onto the planar surface 12 a n− doped epitaxial layer 20 of approximately 30 microns in thickness, the epitaxial layer 20 having a selected resistivity and thickness in accordance with a desired breakdown voltage requirement. An oxide layer 30 is deposited on the layer 20 (FIG. 1). A first etch into the oxide layer 30 defines a pattern of rectangular areas and leaves oxide on top of those areas as a mask (FIG. 2). The epitaxial layer 20 is then preferentially etched down to the planar surface 12 leaving mesas 40 having exposed side walls 42. The masking and etching steps required to accomplish this result are well known in the art of planar fabricated micro-devices. Next, an oxide layer 50, such as silicon oxide, is deposited onto the mesas 40 and their side walls 42 (FIG. 3). Windows 60, smaller than the original rectangular mesa are exposed through the oxide layer 50 by etching on top of the mesas 40 thereby defining contact areas 44. Next, a high concentration of a n++ type dopant is diffused into the windows 60 to establish an ohmic contact surface 62, and a metal conductive layer 70, such as titanium-nickel gold, chromium-gold, titanium-nickel-silver or aluminum, is deposited over the windows 60 to enable circuit contact with the TVS devices (FIG. 4). Finally, the base material 10 is bonded to a substrate 80 and cuts 82 are made through the base material 10 so as to separate adjacent pairs of the mesas 40 thereby providing plural bi-polar devices on the substrate 80 (FIG. 5). The substrate 80 is preferably thereafter cut so as to provide units having a desired number of the TVS devices as for instance the 24 devices shown in FIG. 6.

The starting material, as described above, for a n−/p+ TVS diode is an p++ silicon wafer with a n− epitaxial deposited layer. For an p−/n+ TVS diode, the resistivity types are reversed.

The substrate 80 is a non-conductor such as ceramic, oxidized silicon or Pyrex® glass to name just a few possibilities. Bonding to an oxidized silicon substrate is accomplished by anodic bonding: For other substrates 80, the silicon wafer is adhesively bonded using epoxy bonding agents 85. Other forms of bonding may be substituted as will be known to those of skill in the art. After bonding, diode pairs (units 90) are isolated by sawing through the silicon wafer as shown in FIGS. 5 and 6 where an air gap 82 is formed between units 90. Finally, a desired number of units 90 are obtained as a single device by sawing fully through the substrate. The resultant units 90 are small scale devices which may be flip-chip mounted or wire bonded onto a printed circuit board as shown in FIG. 6 illustrating a 24 line device. Such a device may be 9.1 mm long by 4.3 mm wide for instance.

The enablements described in detail above are considered novel over the prior art of record and are considered critical to the operation of at least one aspect of the apparatus and its method of use and to the achievement of the above described objectives. The words used in this specification to describe the instant embodiments are to be understood not only in the sense of their commonly defined meanings, but to include by special definition in this specification: structure, material or acts beyond the scope of the commonly defined meanings. Thus if an element can be understood in the context of this specification as including more than one meaning, then its use must be understood as being generic to all possible meanings supported by the specification and by the word or words describing the element.

Using the present method TVS units can be made approximately one-sixth of the size of equivalent operating devices made using individual diodes. Typical spacing between units placed side-by-side is approximately 0.6 mm. This is accomplished, in part, by eliminating the usual external connections between the cathodes of two individual diodes and has the further advantage of reducing parasitic losses.

The definitions of the words or drawing elements described herein are meant to include not only the combination of elements which are literally set forth, but all equivalent structure, material or acts for performing substantially the same function in substantially the same way to obtain substantially the same result. In this sense it is therefore contemplated that an equivalent substitution of two or more elements may be made for any one of the elements described and its various embodiments or that a single element may be substituted for two or more elements in a claim.

Changes from the claimed subject matter as viewed by a person with ordinary skill in the art, now known or later devised, are expressly contemplated as being equivalents within the scope intended and its various embodiments. Therefore, obvious substitutions now or later known to one with ordinary skill in the art are defined to be within the scope of the defined elements. This disclosure is thus meant to be understood to include what is specifically illustrated and described above, what is conceptually equivalent, what can be obviously substituted, and also what incorporates the essential ideas.

The scope of this description is to be interpreted only in conjunction with the appended claims and it is made clear, here, that each named inventor believes that the claimed subject matter is what is intended to be patented.

What is claimed is:

1. A method of fabricating plural bipolar transient voltage suppressors comprising the steps of:
a) preparing a highly concentrated p-doped base material having a planar surface;
b) depositing onto the planar surface, an n-doped epitaxial layer, the epitaxial layer having a selected resistivity and thickness in accordance with a given breakdown voltage requirement;
c) preferentially etching the epitaxial layer to the planar surface leaving mesas having exposed side walls;
d) passivating the mesas and side walls with an oxide layer;
e) etching windows in the oxide layer on the mesas thereby defining contact areas;
f) diffusing a n type dopant into the windows to establish ohmic contact surfaces;
g) depositing a conductor metal in the windows;
h) bonding the base material to a substrate; and
i) cutting through the base material so as to separate the mesas into adjacent pairs thereby providing plural bi-polar devices on the substrate.

2. A method of fabricating plural bipolar transient voltage suppressors comprising the steps of:
a) preparing a highly concentrated n-doped base material having a planar surface;
b) depositing onto the planar surface, a p-doped epitaxial layer, the epitaxial layer having a selected resistivity and thickness in accordance with a given breakdown voltage requirement;
c) preferentially etching the epitaxial layer to the planar surface leaving mesas having exposed side walls;
d) passivating the mesas and side walls with an oxide layer;
e) etching windows in the oxide layer on the mesas thereby defining contact areas;
f) diffusing an p+ type dopant into the windows to establish ohmic contact surfaces;
g) depositing a conductor metal into the windows;
h) bonding the base material to a substrate; and
i) cutting through the base material to separate the mesas into adjacent pairs to provide plural bi-polar devices on the substrate.
